(19) United States
(12) Patent Application Publication
(10) Pub. No.: US 2026/0255525 A1
(43) Pub. Date: Aug. 27, 2026

(54) COMPUTING SYSTEM FEATURING TRAY-MOUNTED BACKPLANE INTERCONNECTION MODULES

(71) Applicant: Microsoft Technology Licensing, LLC, Redmond, WA (US)

(72) Inventors: Jason David ADRIAN, Woodinville, WA (US); Wilson V. VU, Bellevue, WA (US); Joel Jonothan JARAMILLO, Colorado Springs, CO (US); Harsha BOJJA, Sunnyvale, CA (US)

(73) Assignee: Microsoft Technology Licensing, LLC, Redmond, WA (US)

(21) Appl. No.: 19/060,340

(22) Filed: Feb. 21, 2025

(51) Int. Cl. H05K 7/14

(52) U.S. Cl. CPC H05K 7/1492; H05K 7/1489

(57) ABSTRACT

A computing system includes an equipment rack, a plurality of backplane devices mounted to the equipment rack to form a connector array, and a plurality of rack trays mounted to the equipment rack. Each rack tray is dockable with a set of the backplane devices by independently translating relative to the equipment rack along a tray-specific translation path. Computing units and backplane interconnection modules can be mounted to each rack tray. A rear set of connectors of each module connects to a set of connectors of the connector array when the rack tray is docked with the set of backplane devices. Each computing unit is dockable with a module by independently translating relative to the rack tray along a unit-specific translation path. Each computing unit includes a set of connectors that connect to a unit-specific set of connectors of the module when the computing unit is docked with the module.

### BACKGROUND

Modern computing increasingly takes place in data center environments. Particularly with the rise of large machine learning (ML) models, the need for increased computing power has risen dramatically. The cost of deploying and operating computing units used to handle computing tasks such as model training and inference is significant. Further, the computing time to train large ML models can be lengthy and costly. As a result, technical challenges exist to improve data center hardware, to increase performance and control costs, for the increasing computing demands of the modern ML era.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A disclosed computing system includes an equipment rack, and a plurality of backplane devices mounted to the equipment rack to form a backplane connector array that extends in a first dimension (e.g., a height dimension) and a second dimension (e.g., a lateral dimension) that is orthogonal to the first dimension. As an example, the plurality of backplane devices can include a plurality of network switches. Additionally, in some examples, the plurality of backplane devices can further include one or more electrical power buses.

The computing system further includes a plurality of rack trays mounted to the equipment rack in a stacked tray configuration in the first dimension. Each rack tray is dockable with two or more of the plurality of backplane devices by independently translating relative to the equipment rack along a tray-specific translation path in a third dimension (e.g., a depth dimension) that is orthogonal to the first dimension and the second dimension.

For each rack tray of the plurality of rack trays, the computing system further includes one or more backplane interconnection modules mounted to the rack tray in which each backplane interconnection module includes a rear set of two or more module-side electronic connectors on a rear side of the backplane interconnection module that connect to a set of two or more backplane-side electronic connectors of the backplane connector array when the rack tray is docked with the two or more backplane devices.

For each rack tray of the plurality of rack trays, the computing system further includes a plurality of computing units mounted to the rack tray in which each computing unit is dockable with a corresponding backplane interconnection module of the one or more backplane interconnection modules mounted to the rack tray by independently translating relative to the rack tray along a unit-specific translation path in the third dimension. Each computing unit includes a set of one or more unit-side electronic connectors that connect to a unit-specific set of one or more module-side electronic connectors on a front side of the corresponding backplane interconnection module when the computing unit is docked with the backplane interconnection module.

Each backplane interconnection module includes two or more unit-specific sets of module-side electronic connectors on the front side for connection to two or more computing units of the plurality of computing units, enabling each backplane interconnection module to connect to and be dockable with two or more computing units of the computing system.

### BRIEF DESCRIPTION OF THE DRAWINGS

FIG. 1 is a perspective view of an example computing system.

FIG. 2 is a perspective view of the computing system of FIG. 1 in which exterior surfaces have been omitted to reveal additional components.

FIG. 3 is a perspective view of the computing system of FIG. 1 in which a rack tray has been undocked and removed from a rack bay.

FIG. 4 is a perspective view of a rack tray of the computing system of FIG. 1.

FIG. 5 is a perspective view of the computing system of FIG. 1 in which a computing unit has been undocked and removed from a unit bay.

FIG. 6 is a perspective view of a computing unit of the computing system of FIG. 1.

FIG. 7 is an elevation view of a portion of the computing system of FIG. 1.

FIG. 8 is an elevation view of a portion of the computing system of FIG. 1 in which a rack tray has been undocked and removed from a rack bay.

FIG. 9 is an elevation view of a portion of the computing system of FIG. 1 in which a computing unit has been undocked and removed from a unit bay.

FIG. 10 is an elevation view of a portion of another example computing system.

FIG. 11 is a schematic diagram depicting an example of electrical interconnects of a backplane interconnection module that can be mounted to a rack tray.

### DETAILED DESCRIPTION

As briefly introduced above, a disclosed computing system includes an equipment rack, and a plurality of backplane devices mounted to the equipment rack to form a backplane connector array that extends in a first dimension (e.g., a height dimension) and a second dimension (e.g., a lateral dimension) that is orthogonal to the first dimension. As an example, the plurality of backplane devices can include a plurality of network switches. Additionally, in some examples, the plurality of backplane devices can further include one or more electrical power buses.

The computing system further includes a plurality of rack trays mounted to the equipment rack in a stacked tray configuration in the first dimension. Each rack tray is dockable with two or more of the plurality of backplane devices by independently translating relative to the equipment rack along a tray-specific translation path in a third dimension (e.g., a depth dimension) that is orthogonal to the first dimension and the second dimension.

For each rack tray of the plurality of rack trays, the computing system further includes one or more backplane interconnection modules mounted to the rack tray in which each backplane interconnection module includes a rear set of two or more module-side electronic connectors on a rear side of the backplane interconnection module that connect to a set of two or more backplane-side electronic connectors of the backplane connector array when the rack tray is docked with the two or more backplane devices.

For each rack tray of the plurality of rack trays, the computing system further includes a plurality of computing units mounted to the rack tray in which each computing unit is dockable with a corresponding backplane interconnection module of the one or more backplane interconnection modules mounted to the rack tray by independently translating relative to the rack tray along a unit-specific translation path in the third dimension. Each computing unit includes a set of one or more unit-side electronic connectors that connect to a unit-specific set of one or more module-side electronic connectors on a front side of the corresponding backplane interconnection module when the computing unit is docked with the backplane interconnection module.

Each backplane interconnection module includes two or more unit-specific sets of module-side electronic connectors on the front side for connection to two or more computing units of the plurality of computing units, enabling each backplane interconnection module to connect to and be dockable with two or more computing units of the computing system. In at least some examples, this configuration enables each of the two or more computing units that is docked with a corresponding backplane interconnection module to exchange electronic communications with any of the backplane devices with which that corresponding backplane interconnection module is docked.

Each computing unit of the computing system can be undocked from the corresponding backplane interconnection module and removed from a unit bay of the rack tray by translating along the unit-specific translation path in the third dimension relative to its rack tray. Removal of a computing unit from the unit bay of its rack tray enables the computing unit to be replaced or repaired without undocking or disconnecting other computing units of the rack tray. Additionally, removal of a computing unit from the unit bay of its rack tray enables access to and replacement or repair of the unit-specific set of module-side electronic connectors of the corresponding backplane interconnection module through the unit bay.

Each rack tray of the computing system can be undocked from the two or more backplane devices and removed from a rack bay of the equipment rack by translating along the tray-specific translation path in the third dimension relative to the equipment rack. Removal of a rack tray from its rack bay of the equipment rack enables the rack tray as well as the computing units and backplane interconnection modules that are mounted to that rack tray to be replaced or repaired without undocking or disconnecting other rack trays and their respective computing units and modules. Additionally, removal of a rack tray from its rack bay of the equipment rack enables access to and replacement or repair of the set of backplane-side electronic connectors of the backplane connector array through the rack bay.

The disclosed computing system offers the potential to provide a spatially compact design that reduces an electrical path distance between computing units and backplane devices while also enabling accessibility and serviceability with respect to components of the computing system. Additionally, the disclosed computing system offers the potential to interconnect large quantities of network switches with large quantities of computing units in a manner that effectively manages complex routing of communication pathways in vertical, lateral, and depth dimensions, while also supporting flexibility in routing of electronic communications between or among the computing units and backplane devices.

As an example, the disclosed computing system can enable replacement or repair of components on a per computing unit basis and on a per rack tray basis without disconnecting or terminating operations associated with other computing units or rack trays of the computing system. Furthermore, by reducing the electrical path distance between computing units and backplane devices, it may be possible to improve signal integrity and/or eliminate or reduce the use of signal amplifiers along electrical pathways between the computing units and the backplane devices.

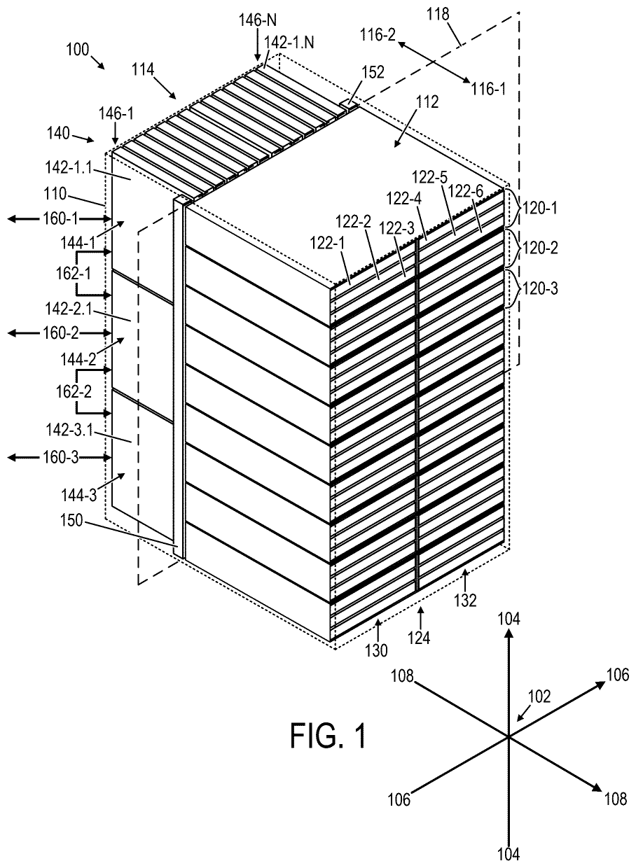

FIG. 1 is a perspective view of an example computing system 100. Computing system 100 is depicted in FIG. 1 within the context of a three-dimensional coordinate system 102 that has a first dimension 104, a second dimension 106 that is orthogonal to first dimension 104, and a third dimension 108 that is orthogonal to first dimension 104 and second dimension 106. As an example, first dimension 104 can refer to a vertical dimension, second dimension 106 can refer to a lateral dimension, and third dimension 108 can refer to a depth dimension of computing system 100.

Computing system 100 includes an equipment rack 110 that forms a frame or enclosure to which other components can be mounted. In FIG. 1, equipment rack 110 is depicted in wireframe to reveal additional components of computing system 100 that are mounted to the equipment rack.

Computing system 100 includes a plurality of rack trays 112 mounted to equipment rack 110. Computing system 100 further includes a plurality of backplane devices 114 mounted to equipment rack 110. In the example of FIG. 1, the plurality of rack trays 112 are located on a first side 116-1 of a virtual backplane 118 of computing system 100, and the plurality of backplane devices 114 are located on a second side 116-2 of the virtual backplane opposite first side 116-1. In this example, virtual backplane 118 takes the form of a two-dimensional plane in first dimension 104 and second dimension 106, and is orthogonal to third dimension 108.

In the example of FIG. 1, the plurality of rack trays 112 includes nine rack trays of which a first rack tray 120-1, a second rack tray 120-2, and a third rack tray 120-3 are examples. It will be understood that the plurality of rack trays 112 can include any suitable quantity of two or more rack trays, including fewer or greater quantities of rack trays from the example depicted in FIG. 1.

The plurality of rack trays 112, in the example of FIG. 1, are mounted to equipment rack 110 to form a stacked tray configuration 124 in first dimension 104 (e.g., the height dimension). For example, first rack tray 120-1 is located above second rack tray 120-2, third rack tray 120-3 is located below second rack tray 120-2, and the remaining rack trays are located below third rack tray 120-3 within stacked tray configuration 124.

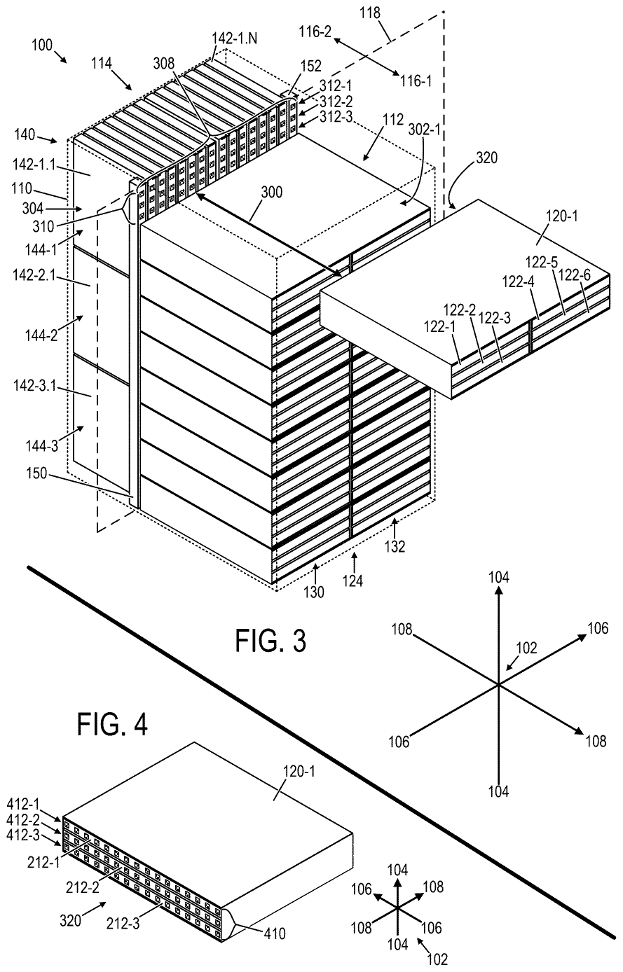

As described in further detail with reference to FIG. 3, each rack tray of the plurality of rack trays 112 is independently translatable relative to equipment rack 110 along a tray-specific translation path in third dimension 108 (e.g., the depth dimension). As each rack tray is independently translatable relative to equipment rack 110, a given rack tray can be translated along its tray-specific translation path to enable that rack tray to be docked or undocked with respect to backplane devices 114 without requiring translation of other rack trays of computing system 100.

For each rack tray of the plurality of rack trays 112, computing system 100 includes a plurality of computing units that are mounted to that rack tray. In the example of FIG. 1, six computing units are mounted to each of the plurality of rack trays 112 of computing system 100. For example, computing units 122-2, 122-3, 122-4, 122-5, 122-6, 122-7, and 122-8 are mounted to rack tray 120-1, as depicted in FIG. 1. It will be understood that any suitable quantity of computing units can be mounted to each of rack trays 112, including fewer or greater quantities of computing units from the example depicted in FIG. 1.

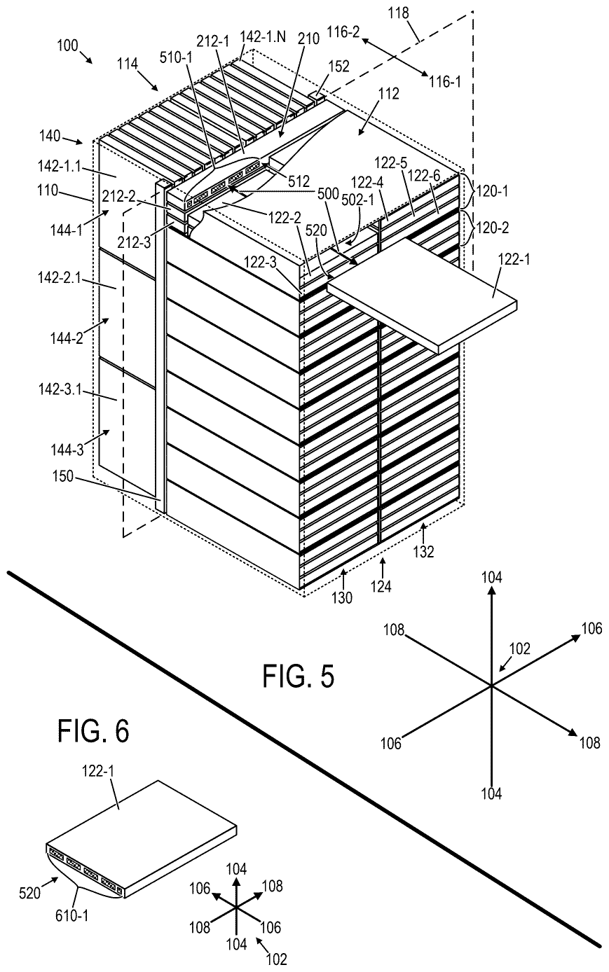

As described in further detail with reference to FIG. 5, each computing unit is independently translatable relative to its rack tray along a unit-specific translation path in the third dimension 108 (e.g., the depth dimension). As each computing unit is independently translatable relative to its rack tray, a given computing unit can be translated along its unit-specific translation path to dock or undock that computing unit without requiring translation of other computing units of the rack tray.

In at least some examples, computing units of computing system 100 can be arranged in a stacked unit configuration in first dimension 104 (e.g., the height dimension). In the example of FIG. 1, a subset of the computing units are mounted to the rack trays of computing system 100 in a first stacked unit configuration 130, and another subset of the computing units are mounted to the rack trays of computing system 100 in a second stacked unit configuration 132.

For example, computing units 122-1, 122-2, 122-3 mounted to rack tray 120-1 form part of first stacked unit configuration 130 in which computing unit 122-1 is located above computing unit 122-2, and computing unit 122-3 is located below computing unit 122-2 in first dimension 104. Additionally, in this example, computing units 122-4, 122-5, and 122-6 mounted to rack tray 120-1 form part of second stacked unit configuration 132 in which computing unit 122-4 is located above computing unit 122-5, and computing unit 122-6 is located below computing unit 122-5.

First stacked unit configuration 130 and second stacked unit configuration 132 are arranged side-by-side in second dimension 106 (e.g., the lateral dimension) in the example of FIG. 1. In other examples, three or more stacked unit configurations of computing units can be arranged side-by-side in second dimension 106. In still other examples, computing system 100 can include a single stacked unit configuration of computing units.

The plurality of backplane devices 114 of computing system 100 can include a plurality of network switches 140 mounted to equipment rack 110. Network switches 140 can be operated to route electronic communications between and among computing units of computing system 100 and remote network devices located off-board the computing system. In the example of FIG. 1, network switches 140 are arranged in a two-dimensional array in first dimension 104 (e.g., the height dimension) and second dimension 106 (e.g., the lateral dimension) on second side 116-2 of backplane 118.

In FIG. 1, examples of network switches 140 include network switch 142-1.1 through network switch 142-N that form a first switch tier 144-1 that extends in second dimension 106 (e.g., the lateral dimension), where the term “N” of 142-N can refer to any suitable quantity of network switches per switch tier. In the example of FIG. 1, the term “N” refers to fourteen network switches of each switch tier in second dimension 106. It will be understood that fewer or greater quantities of network switches can be included in each switch tier.

Additional examples of network switches 140 include network switch 142-2.1 that forms part of a second switch tier 144-2, and network switch 142.3.1 that forms part of a third switch tier 144-3. In this example, second switch tier 144-2 and third switch tier 144-3 can each include the same quantity of network switches as first switch tier 144-1 (e.g., a quantity of “N” network switches per switch tier). It will be understood that computing system 100 can include any suitable quantity of switch tiers mounted to equipment rack 110 that extend in second dimension 106, including fewer or greater quantities of switch tiers from the example depicted in FIG. 1.

In the example of FIG. 1, network switches 140 are further arranged in switch columns 146-1 through 146-N that extend in first dimension 104, where the term “N” in 146-N again refers to the quantity of network switches per switch tier. For example, switch column 146-1 includes network switch 142-1.1 of switch tier 144-1, network switch 142-2.1 of switch tier 144-2, and network switch 142-3.1 of switch tier 144-3. As another example, switch column 146-N includes network switch 142-1.N of switch tier 144-1, network switch 142-2.N of switch tier 144-2, and network switch 142-3.N of switch tier 144-3.

As described in further detail with reference to FIG. 3, network switches of each switch tier can be docked with and connected to components that are mounted to a particular subset of the plurality of rack trays 112. In the example of FIG. 1, each of switch tiers 144-1, 144-2, and 144-3 are docked with and connected to components mounted to three rack trays of the plurality of rack trays 112. For example, network switches 142.1.1 through 142-1.N of first switch tier 144-1 are docked with and connected to components that are mounted to rack trays 120-1, 120-2, and 120-3. It will be understood that each switch tier can be docked with and connected to components of any suitable quantity of rack trays, including lesser or greater quantities of rack trays from the example depicted in FIG. 1.

Connections between network switches 140 and electronic components mounted to rack trays 112 can be provided by electronic connectors that convey electronic communications (e.g., data). Electronic connectors that convey electronic communications can be referred to herein as data connectors. Each data connector can include a set of electrical contacts or pins by which that connector connects to another connector. In this example, each electrical contact or pin can correspond to a respective lane for conveying data. A data connector that can convey multiple lanes of data can be referred to herein as a multi-lane data connector.

In some examples, the plurality of backplane devices 114 can further include one or more electrical power buses mounted to equipment rack 110 by which electrical power can be supplied to the computing units of the computing system. As described in further detail herein, electrical connections between electrical power buses and electronic components mounted to rack trays 112 can be provided by electronic connectors that convey electrical power, which can include electrical potential and electrical ground pathways. Electronic connectors that convey electrical power can be referred herein to as electrical power connectors.

In the example of FIG. 1, computing system 100 includes a first electrical power bus 150 by which electrical power can be supplied to the computing units of first stacked unit configuration 130. Additionally, computing system 100 includes a second electrical power bus 152 by which electrical power can be supplied to the computing units of second stacked unit configuration 132. In FIG. 1, first electrical power bus 150 and second electrical power bus 152 are located on second side 116-2 of backplane 118, extend in first dimension 104 along a rear side of rack trays 112. Furthermore, in this example, network switches 140 are located between electrical power buses 150 and 152 in second dimension 106. In other examples, second electrical power bus 152 can be omitted, and first electrical power bus 150 can supply electrical power to each of the computing units of computing system 100, including the computing units of first stacked unit configuration 130, second stacked unit configuration 132, and any additional stacked configurations of computing units.

In at least some examples, each of the plurality of network switches 140 can include one or more backline network connections to remote networking devices and/or communications networks. In FIG. 1, example backline network connections 160-1, 160-2, and 160-3 are depicted with respect to network switches 142-1.1, 142-2.1, and 142-3.1, respectively. In at least some examples, computing units of computing system 100 can communicate with remote network devices and/or communications networks over one or more of the backline network connections (e.g., 160-1, 160-2, and 160-3) by sending and/or receiving electronic communications that traverse one or more of the plurality of network switches 140.

In at least some examples, each of the plurality of network switches 140 can include one or more inter-switch connections to one or more other network switches of the plurality of network switches 140. As an example, each of the plurality of network switches 140 can include one or more inter-switch connections to neighboring switch tiers to enable electronic communications to be exchanged between the switch tiers. In FIG. 1, example inter-switch connections 162-1 and 162-2 are depicted with respect to network switches 142-1.1, 142-2.1, and 142-3.1. In this example, inter-switch connection 162-1 enables electronic communications between network switch 142-1.1 of switch tier 144-1 and network switch 142-2.1 of switch tier 144-2. As another example, inter-switch connection 162-2 enables electronic communications between network switch 142-2.1 of switch tier 144-2 and network switch 142-3.1 of switch tier 144-3.

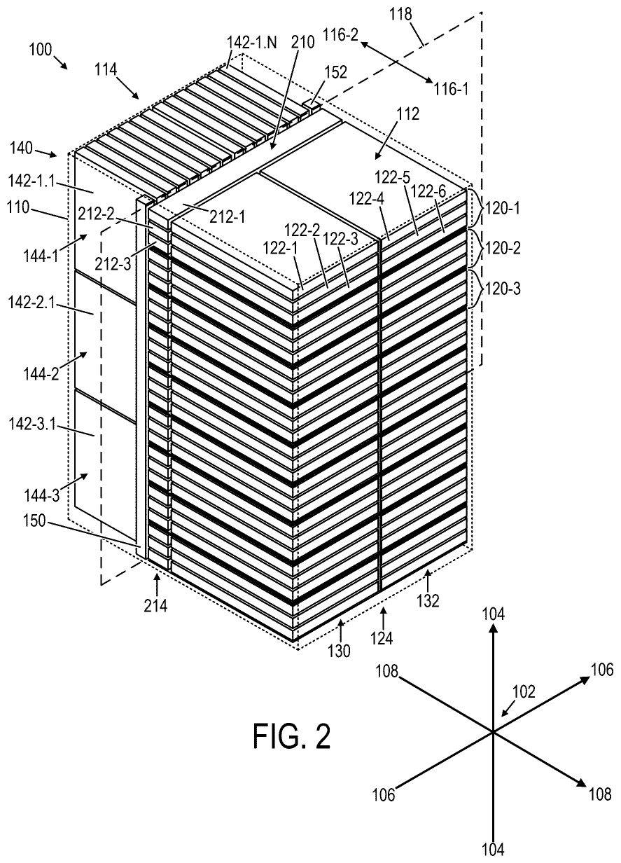

FIG. 2 is a perspective view of computing system 100 having the same perspective as FIG. 1. In FIG. 2, exterior surfaces of the plurality of rack trays 112 that were depicted in FIG. 1 have been omitted to reveal additional components of computing system 100.

For each rack tray of the plurality of rack trays 112, computing system 100 includes a set of one or more backplane interconnection modules 210 that are mounted to the rack tray. As described in further detail herein, the set of one or more backplane interconnection modules 210 mounted to each rack tray can interconnect two or more computing units mounted to the rack tray with two or more of backplane devices 114.

In the example of FIG. 2, each of backplane interconnection modules 210 extends in second dimension 106 over a range that spans electronic connectors of the network switches of a switch tier, which enables connection of each backplane interconnection module to the network switches of that switch tier. For example, each of backplane interconnection modules 212-1, 212-2, and 212-3 that are mounted to rack tray 120-1 extend in second dimension 106 over a range that spans the electronic connectors of network switches 142-1.1 through 142-1.N of first switch tier 144-1, which enables connection of each of backplane interconnection modules 212-1, 212-2, and 212-3 to each network switch of first switch tier 144-1.

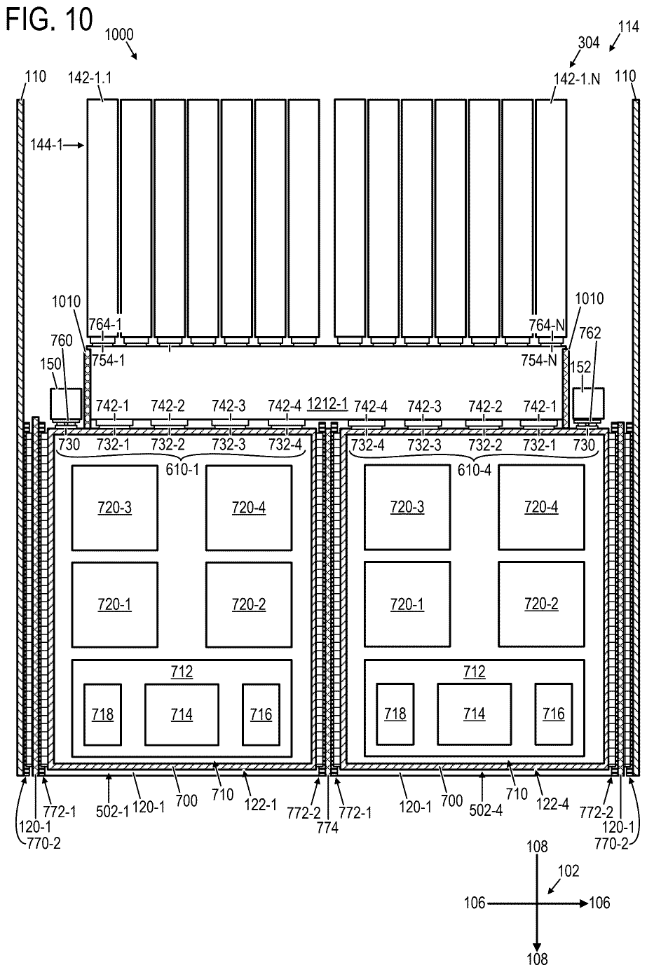

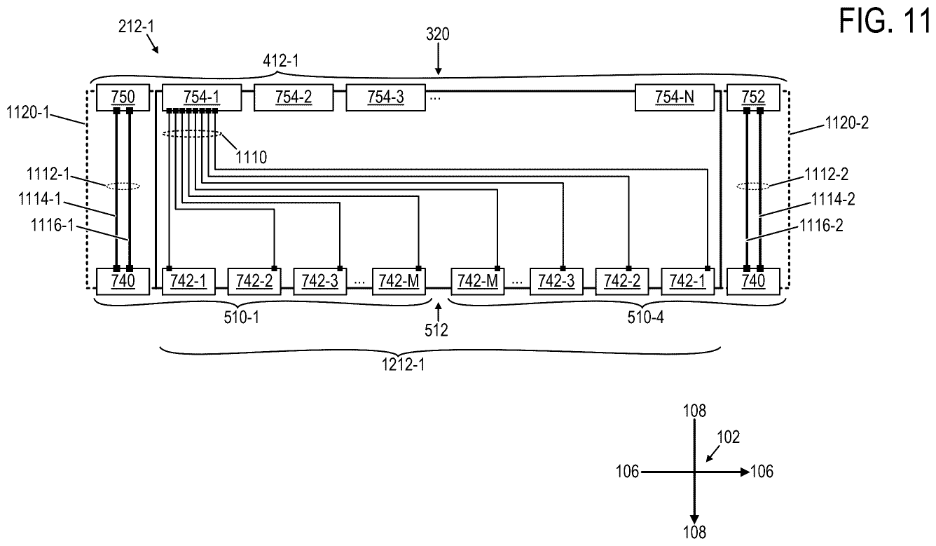

Additionally, in the example of FIG. 1, each of backplane interconnection modules 210 extends in second dimension 106 over a range that spans electronic connectors of first electrical power bus 150 and second electrical power bus 152, which enables interconnection of the electrical power buses with computing units of computing system 100. In other examples, first electrical power bus 150 and second electrical power bus 152 can be connected to the computing units of computing system 100 without traversing the backplane interconnection modules, as described in further detail with reference to FIGS. 10 and 11.

Each backplane interconnection module that is mounted to a rack tray can interconnect two or more computing units with two or more of backplane devices 114. In the example of FIG. 2, three backplane interconnection modules are mounted to each rack tray, which corresponds to the quantity of computing units mounted to each rack tray in first dimension 104 (e.g., the height dimension). For example, three backplane interconnection modules 212-1, 212-2, and 212-3 are mounted to rack tray 120-1, which corresponds to a quantity of three computing units (e.g., 122-1, 122-2, 122-3) mounted to the rack tray in first dimension 104.

Furthermore, each of backplane interconnection modules 210 extends in second dimension 106 over a range that spans data connectors of a first computing unit of first stacked unit configuration 130 and data connectors of a second computing unit of second stacked unit configuration 132 to enable interconnection of these computing units with the backplane interconnection module. For example, backplane interconnection module 212-1 extends in second dimension 106 over a range that that spans data connectors of computing units 122-1 and 122-4. Similarly, backplane interconnection module 212-2 extends in second dimension 106 over a range that spans data connectors of computing units 122-2 and 122-5. It will be understood that any suitable quantity of one or more backplane interconnection modules can be mounted to each of the plurality of rack trays 112, including fewer or greater quantities of backplane interconnection modules from the example depicted in FIG. 2.

In the preceding examples, each backplane interconnection module spans the data connectors of two computing units in second dimension 106 (e.g., the lateral dimension) such that the backplane interconnection module is located between these computing units and backplane devices 114 in third dimension 108 (e.g., the depth dimension). In this example, the set of backplane interconnection modules 210 are mounted to equipment rack 110 in a stacked device configuration 214 in first dimension 104 (e.g., the height dimension). In other examples, each backplane interconnection module can alternatively or additionally extend in first dimension 104 over a range that spans two or more computing units in the first dimension (e.g., the height dimension).

As briefly introduced above, each computing unit of computing system 100 is dockable with a corresponding backplane interconnection module within a unit bay of a rack tray by independently translating relative to the rack tray along a unit-specific translation path in third dimension 108 (e.g., the depth dimension). In FIGS. 1 and 2, for example, each of the computing units of computing system 100 are docked with a corresponding backplane interconnection module. When a computing unit is docked with its corresponding backplane interconnection module, the set of one or more electronic connectors of the computing unit are connected to a corresponding set of one or more electronic connectors on the front side of that backplane interconnection module.

Additionally, as briefly introduced above, each rack tray of the plurality of rack trays 112 is dockable with two or more backplane devices of the plurality of backplane devices 114 within a rack bay of equipment rack 110 by independently translating relative to equipment rack 110 along a tray-specific translation path in third dimension 108 (e.g., the depth dimension). In FIGS. 1 and 2, for example, each of the plurality of rack trays 112 are docked with the network switches of a corresponding switch tier, and with electrical power buses 150 and 152. In this example, rack trays 120-1, 120-2, and 120-3 are docked with network switches 142-1.1 through 142-1.N of switch tier 144-1, and with electrical power buses 150 and 152. When a rack tray is docked with two or more of backplane devices 114, backplane-side electronic connectors of the two or more of the backplane devices 114 are connected to module-side electronic connectors on a rear side of the backplane interconnection modules of that rack tray.

FIG. 3 is a perspective view of computing system 100 having the same perspective as FIGS. 1 and 2. In FIG. 3, rack tray 120-1 is undocked from a tray-specific group of backplane devices 304 of the plurality of backplane devices 114 by rack tray 120-1 being translated relative to equipment rack 110 along a tray-specific translation path 300 in third dimension 108 (e.g., the depth dimension). Additionally, in FIG. 3, rack tray 120-1 is removed from its corresponding rack bay 302-1 of equipment rack 110 by being translated relative to the equipment rack along tray-specific translation path 300. In this example, rack tray 120-1 has been translated along unit-specific translation path 300 independent of other rack trays (e.g., 120-2) of the plurality of rack trays 112 of computing system 100.

As depicted in FIG. 3, translation of rack tray 120-1 along tray-specific translation path 300 in third dimension 108 is away from virtual backplane 118 and away from the tray-specific group of backplane devices 304. Each rack tray of computing system 100 can be undocked from its corresponding tray-specific group of backplane devices and removed from its corresponding rack bay of equipment rack 110 by being translated along its tray-specific translation path in third dimension 108 relative to the equipment rack.

The plurality of backplane devices 114 collectively form a backplane connector array 308 of backplane-side electronic connectors that extends in first dimension 104 and a second dimension 106. Each backplane device of the plurality of backplane devices 114 includes one or more backplane-side electronic connectors of backplane connector array 308. FIG. 3 schematically depicts a portion of backplane connector array 308 of the plurality of backplane devices 114 that has been revealed by removal of rack tray 120-1 from rack bay 302-1.

For each of the plurality of rack trays 112 of computing system 100, backplane connector array 308 includes a tray-specific group of backplane-side electronic connectors by which components mounted to the rack tray can connect to a tray-specific group of backplane devices of the plurality of backplane devices 114. For example, a tray-specific group of backplane devices 304 for rack tray 120-1 includes network switches 142-1.1 through 142-1.N of switch tier 144-1, and electrical power buses 150 and 152. The tray-specific group of backplane devices 304 for rack tray 120-1 includes a tray-specific group 310 of backplane-side electronic connectors that are connected to components mounted to the rack tray when docked, as shown in FIGS. 1 and 2.

For example, the tray-specific group 310 of backplane-side electronic connectors includes a first set 312-1 of backplane-side electronic connectors for connection to backplane interconnection module 212-1, a second set 312-2 of backplane-side electronic connectors for connection to backplane interconnection module 212-2, and a third set 312-3 of backplane-side electronic connectors for connection to backplane interconnection module 212-3. It will be understood that backplane connector array 308 includes additional tray-specific groups of backplane-side electronic connectors for connection to backplane interconnection modules that are mounted to other rack trays of computing system 100. When rack tray 120-1 is undocked from the tray-specific group of backplane devices 304, as depicted in FIG. 3, the tray-specific group 310 of backplane-side electronic connectors are disconnected from module-side electronic connectors of backplane interconnection modules 212-1, 212-2, and 212-3 located on a rear side 320 of rack tray 120-1.

FIG. 4 is a perspective view of rack tray 120-1 of FIG. 3 in which rear side 320 of the rack tray is visible. FIG. 4 schematically depicts a tray-specific group 410 of module-side electronic connectors on rear side 320 of rack tray 120-1. The tray-specific group 410 of module-side electronic connectors connect to the tray-specific group 310 of backplane-side electronic connectors of backplane connector array 308 when rack tray 120-1 is docked with the tray-specific group of backplane devices 304, enabling electronic communications and/or electrical power to be transferred between the tray-specific group of backplane devices 304 and electronic components mounted to rack tray 120-1.

Each backplane interconnection module includes a rear set of two or more module-side electronic connectors on rear side 320 of the backplane interconnection module that connect to a set of two or more backplane-side electronic connectors of backplane connector array 308 when the rack tray is docked with two or more backplane devices of tray-specific group 310. For example, a rear set 412-1 of two or more module-side electronic connectors of group 410 on rear side 320 of backplane interconnection module 212-1 can connect to the first set 312-1 of backplane-side electronic connectors. Another rear set 412-2 of two or more module-side electronic connectors of group 410 on rear side 320 of backplane interconnection module 212-2 can connect to the second set 312-2 of backplane-side electronic connectors. Another rear set 412-3 of two or module-side electronic connectors of group 410 on rear side 320 of backplane interconnection module 212-3 can connect to the third second 312-3 of backplane-side electronic connectors.

FIG. 5 is a perspective view of computing system 100 having the same perspective as FIGS. 1 and 2. In FIG. 5, computing unit 122-1 is undocked from backplane interconnection module 212-1 of rack tray 120-1 by computing unit 122-1 being translated relative to rack tray 120-1 along a unit-specific translation path 500 in third dimension 108 (e.g., the depth dimension). Additionally, in FIG. 5, computing unit 122-1 is removed from its corresponding unit bay 502-1 of rack tray 120-1 by being translated relative to the rack tray along unit-specific translation path 500. In this example, computing unit 122-1 has been translated along unit-specific translation path 500 independent of other computing units (e.g., 122-2 through 122-6) of rack tray 120-1 and of computing system 100.

In FIG. 5, a portion of rack tray 120-1 has been omitted to show features of backplane interconnection module 212-1. Each backplane interconnection module of computing system 100 includes a unit-specific set of one or more module-side electronic connectors on a front side of the backplane interconnection module. For example, FIG. 5 schematically depicts a unit-specific set 510-1 of module-side electronic connectors on a front side 512 of backplane interconnection module 212-1 that can connect to corresponding unit-side electronic connectors of computing unit 122-1 on a rear side 520 of the computing unit.

The unit-specific set 510-1 of module-side electronic connectors of backplane interconnection module 212-1 can include one or more module-side electronic connectors for exchanging electronic communications with computing unit 122-1, for example. Additionally, in some examples, the unit-specific set 510-1 of module-side electronic connectors of backplane interconnection module 212-1 can include one or more module-side electronic connectors for supplying electrical power to computing unit 122-1. It will be understood that the unit-specific set 510-1 of module-side electronic connectors of backplane interconnection module 212-1 can include other suitable quantities and configurations of electronic connectors from the example schematically depicted in FIG. 5.

In at least some examples, two or more computing units mounted to a rack tray are concurrently dockable with the same corresponding backplane interconnection module. In computing system 100, for example, two computing units are concurrently dockable with each backplane interconnection module. In this example, a first computing unit of stacked unit configuration 130 and a second computing unit of stacked unit configuration 132 are concurrently dockable with each backplane interconnection module of computing system 100. For example, computing units 122-1 and 122-4 are concurrently dockable with backplane interconnection module 212-1, computing units 122-2 and 122-5 are concurrently dockable with backplane interconnection module 212-2, and computing units 122-3 and 122-6 are concurrently dockable with backplane interconnection module 212-3. In the example of FIG. 5, computing unit 122-1 is undocked from backplane interconnection module 212-1 while computing unit 122-4 is docked with backplane interconnection module 212-1. In each of these preceding examples, the computing units that are concurrently dockable with the same corresponding backplane interconnection module are mounted to the rack tray in a side-by-side unit configuration in the second dimension 106.

FIG. 6 is a perspective view of computing unit 122-1 of FIG. 5 in which rear side 520 of the computing unit is visible. FIG. 6 schematically depicts a set of unit-side electronic connectors 610-1 on rear side 520 of computing unit 122-1. When computing unit 122-1 is docked with backplane interconnection module 212-1, as depicted in FIGS. 1-3, the unit-specific set 510-1 of module-side electronic connectors of backplane interconnection module 212-1 are connected to the set of unit-side electronic connectors 610-1 of computing unit 122-1. When computing unit 122-1 is undocked from backplane interconnection module 212-1, as depicted in FIG. 5, the set of unit-side electronic connectors 610-1 of computing unit 122-1 are disconnected from the unit-specific set 510-1 of module-side electronic connectors of backplane interconnection module 212-1. It will be understood that the set unit-side electronic connectors 610-1 of computing unit 122-1 can include other suitable quantities and configurations of electronic connectors from the example schematically depicted in FIG. 6.

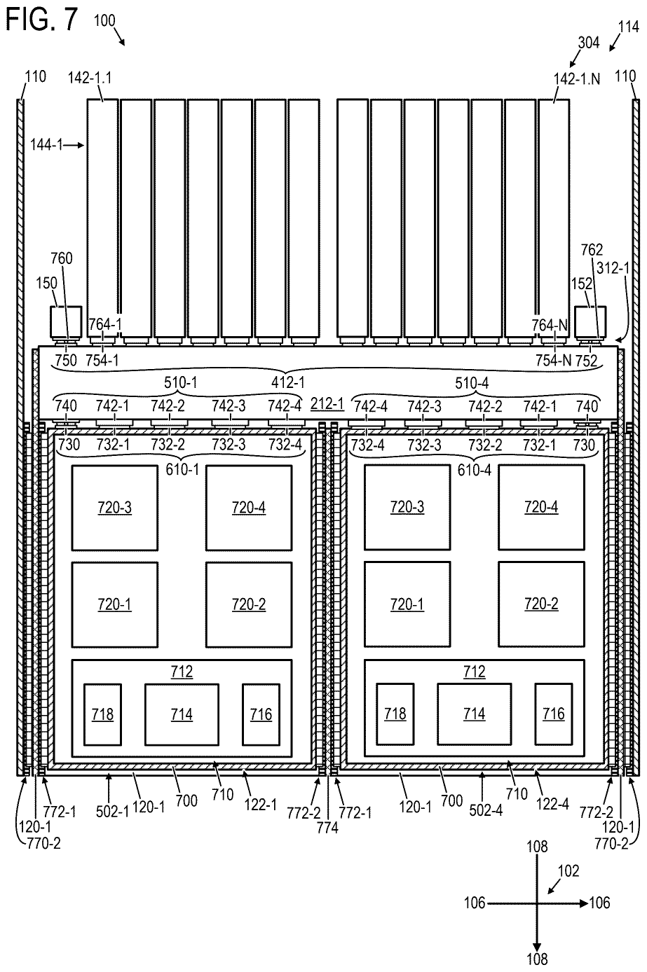

FIG. 7 is an elevation view of a portion of computing system 100 of FIG. 1 that depicts backplane interconnection module 212-1, and computing units 122-1 and 122-4 mounted to rack tray 120-1, as viewed along first dimension 104 (e.g., the height dimension). In the example of FIG. 7, computing units 122-1 and 122-4 are mounted to rack tray 120-1 in a side-by-side configuration in second dimension 106, and computing units 122-1 and 122-4 are concurrently docked with backplane interconnection module 212-1 within unit bays 502-1 and 502-4, respectively. Additionally, in this example, rack tray 120-1 is mounted to equipment rack 110, and rack tray 120-1 is docked with backplane devices 304 within rack bay 302-1.

Each of the computing units of computing system 100 can include an enclosure and a set of one or more electronic components mounted to the enclosure. For example, as described with reference to computing units 122-1 and 122-4, each computing unit includes an enclosure 700 and a set of electronic components 710 mounted to the enclosure. In this example, electronic components 710 of each computing unit are housed within enclosure 700 of the computing unit. Electronic components 710 of each computing unit can include a primary computing platform 712 that includes a primary logic subsystem 714, a primary data storage subsystem 716, and a power control subsystem 718.

Primary logic subsystem 714 includes one or more logic devices. Logic devices of primary logic subsystem 714 can include one or more computer processor devices, as an example. Primary data storage subsystem 716 includes one or more data storage devices, which can have instructions executable by primary logic subsystem 714 and/or other data stored thereon. Data storage devices of primary data storage subsystem 716 can include one or more computer memory devices, as an example. As examples, power control subsystem 718 can include one or more electrical power conditioning devices (e.g., voltage converters, current converters, AC-DC converters, filters, etc.) and/or electrical power distribution devices (e.g., switches, distribution cabling, etc.) for powering electronic components 710.

Electronic components 710 of each computing unit can further include one or more accessory computing devices. As an example, accessory computing devices can include or take the form of one or more accelerator computing devices (e.g., graphics processors) that can be selectively used to accelerate performance of computing tasks associated with or on behalf of primary computing platform 712 of the computing unit. In the example of FIG. 7, the set of electronic components 710 includes four accessory computing devices 720-1, 720-2, 720-3, and 720-4 arranged in an array that extends in second dimension 106 and third dimension 108 of enclosure 700. It will be understood that the set of electronic components 710 can include lesser or greater quantities of accessory computing devices from the example depicted in FIG. 7, or the accessory computing devices can be omitted in other examples.

As previously described with reference to FIGS. 5 and 6, each computing unit includes a set of one or more unit-side electronic connectors that connect to a unit-specific set of module-side electronic connectors on the front side of a corresponding backplane interconnection module when the computing unit is docked with the backplane interconnection module. For example, as computing unit 122-1 is docked with backplane interconnection module 212-1 in FIG. 7, the set of unit-side electronic connectors 610-1 of computing unit 122-1 are connected to the unit-specific set 510-1 of module-side electronic connectors on the front side 512 of the backplane interconnection module. As another example, as computing unit 122-4 is also docked with backplane interconnection module 212-1 in FIG. 7, a set of unit-side electronic connectors 610-4 of computing unit 122-4 are connected to another unit-specific set 510-4 of module-side electronic connectors on the front side of the backplane interconnection module.

In the example of FIG. 7, the set of unit-side electronic connectors 610-1 of computing unit 122-1 includes an electronic connector 730 for conveying electrical power, and one or more electronic connectors (e.g., 732-1, 732-2, 732-3, 732-4) for conveying electronic communications. While the set of unit-side electronic connectors 610-1 is depicted as including five electronic connectors in the example of FIG. 7, it will be understood that computing unit 122-1 can include other suitable quantities of electronic connectors, including lesser or greater quantities of electronic connectors.

The unit-specific set 510-1 of module-side electronic connectors of backplane interconnection module 212-1 includes an electronic connector 740 that is aligned with and can connect to electronic connector 730 of computing unit 122-1 for conveying electrical power, and one or more electronic connectors (e.g., 742-1, 742-2, 742-3, 742-4) that are aligned with and can connect to corresponding electronic connectors (e.g., 732-1, 732-2, 732-3, 732-4) of computing unit 122-1 for conveying electronic communications. While the unit-specific set 510-1 of module-side electronic connectors is depicted as including five electronic connectors in the example of FIG. 7, it will be understood that backplane interconnection module 212-1 can include other suitable quantities of module-side electronic connectors, including lesser or greater quantities of electronic connectors. Furthermore, in other examples, electronic connector 740 for conveying electrical power can be omitted from backplane interconnection module 212-1, as described in further detail with reference to FIGS. 10 and 11.

In the example of FIG. 7, unit-side electronic connectors 610-1 of computing unit 122-1 are distributed along second dimension 106 (e.g., the lateral dimension), and face toward backplane interconnection module 212-1. Additionally, in this example, the unit-specific set 510-1 of module-side electronic connectors of backplane interconnection module 212-1 are distributed along second dimension 106, and face toward computing unit 122-1. Alignment of module-side electronic connectors of the unit-specific set 510-1 with the set of unit-side electronic connectors 610-1 in second dimension 106 can be achieved at any suitable spacing and configuration that enables corresponding connections to be established between computing unit 122-1 and backplane interconnection module 212-1 via their respective connectors.

In the example of FIG. 7, the set of unit-side electronic connectors 610-4 of computing unit 122-4 includes an instance of previously described electronic connector 730 for conveying electrical power, and an instance of previously described electronic connectors 732-1, 732-2, 732-3, 732-4 for conveying electronic communications. While unit-side electronic connectors 610-4 are depicted as including five electronic connectors in the example of FIG. 7, it will be understood that computing unit 122-4 can include other suitable quantities of electronic connectors, including lesser or greater quantities of electronic connectors.

The unit-specific set 510-4 of module-side electronic connectors of backplane interconnection module 212-1 includes an instance of previously described electronic connector 740 that is aligned with and can connect to electronic connector 730 of computing unit 122-4 for conveying electrical power, and an instance of previously described electronic connectors (e.g., 742-1, 742-2, 742-3, 742-4) that are aligned with and can connect to corresponding electronic connectors (e.g., 732-1, 732-2, 732-3, 732-4) of computing unit 122-4 for conveying electronic communications. While the unit-specific set 510-4 of module-side electronic connectors is depicted as including five electronic connectors in the example of FIG. 7, it will be understood that backplane interconnection module 212-1 can include other suitable quantities of module-side electronic connectors, including lesser or greater quantities of electronic connectors. Furthermore, in other examples, electronic connector 740 of the unit-specific set 510-4 of module-side electronic connectors for conveying electrical power can be omitted from backplane interconnection module 212-1, as described in further detail with reference to FIGS. 10 and 11.

In the example of FIG. 7, the set of unit-side electronic connectors 610-4 of computing unit 122-4 is distributed along second dimension 106 (e.g., the lateral dimension), and face toward backplane interconnection module 212-1. Additionally, in this example, the unit-specific set 510-4 of module-side electronic connectors of backplane interconnection module 212-1 is distributed along second dimension 106, and face toward computing unit 122-4. Alignment of module-side electronic connectors of the unit-specific set 510-4 with the set of unit-side electronic connectors 610-4 in second dimension 106 can be achieved at any suitable spacing and configuration that enables corresponding connections to be established between computing unit 122-4 and backplane interconnection module 212-1 via their respective connectors.

In the example of FIG. 7, unit-side electronic connectors 610-4 of computing unit 122-4 include the same quantity and type of electronic connectors as previously described with reference to unit-side electronic connectors 610-1 of computing unit 122-1. However, in this example, an ordering of electronic connectors 610-4 of computing unit 122-4 progresses in an opposite direction in second dimension 106 as compared to electronic connectors 610-1 of computing unit 122-1. For example, electronic connector 730 of the set of unit-side electronic connectors 610-4 is located on the right-hand side of the remaining electronic connectors of the set, whereas electronic connector 730 of the set of unit-side electronic connectors 610-1 is located on the left-hand side of the remaining electronic connectors of the set. It will be understood that electronic connectors of the computing units can have different configurations from the examples depicted in FIG. 7.

FIG. 7 further depicts an example of rack tray 120-1 docked with backplane devices 304 within rack bay 302-1 of equipment rack 110. As rack tray 120-1 is docked with backplane devices 304 in this example, the rear set 412-1 of module-side electronic connectors of backplane interconnection module 212-1 is connected to the backplane-side electronic connectors 312-1 of backplane devices 304.

In the example of FIG. 7, the rear set 412-1 of backplane-side electronic connectors of backplane interconnection module 212-1 includes electronic connectors 750 and 752 for conveying electrical power, and electronic connectors 754-1 through 754-N for conveying electronic communications. In this example, the term “N” in reference numeral 754-N corresponds to the quantity of network switches of a switch tier of backplane devices 304 in second dimension 106.

Furthermore, in the example of FIG. 7, the backplane-side electronic connectors 312-1 of backplane devices 304 includes electronic connectors 760 and 762 for conveying electrical power, and electronic connectors 764-1 through 764-N for conveying electronic communications. In this example, the term “N” in reference numeral 764-N corresponds to the quantity of network switches of backplane devices 304.

Electrical power can be supplied by electrical power bus 150 to computing unit 122-1 via backplane interconnection module 212-1. In this example, electrical power can be conveyed via an electrical potential pathway and an electrical ground pathway of each of electrical power bus 150, connectors 760 and 750, backplane interconnection module 212-1, connector 740 of the unit-specific set 510-1, and connector 730 of computing unit 122-1. For example, electronic connector 750 of backplane interconnection module 212-1 is connected to electronic connector 760 of electrical power bus 150, enabling electrical power to be supplied by electrical power bus 150 to backplane interconnection module 212-1 via electronic connectors 750 and 760. Electrical power supplied to backplane interconnection module 212-1 via electronic connectors 750 and 760 is conveyed by electrical pathways (e.g., electrical potential and ground pathways) of the backplane interconnection module to electronic connector 740 of the unit-specific set 510-1. Electronic connector 740 of the unit-specific set 510-1 is connected to electronic connector 730 of computing unit 122-1, enabling electrical power to be supplied to the computing unit from the backplane interconnection module.

Similarly, electrical power can be supplied by electrical power bus 152 to computing unit 122-4 via backplane interconnection module 212-1. In this example, electrical power can be conveyed via an electrical potential pathway and an electrical ground pathway of each of electrical power bus 150, connectors 760 and 750, backplane interconnection module 212-1, connector 740 of the unit-specific set 510-4, and connector 730 of computing unit 122-1. For example, electronic connector 752 of backplane interconnection module 212-1 is connected to electronic connector 762 of electrical power bus 152, enabling electrical power to be supplied by electrical power bus 152 to backplane interconnection module 212-1 via electronic connectors 752 and 762. Electrical power supplied to backplane interconnection module 212-1 via electronic connectors 752 and 762 is conveyed by electrical pathways (e.g., electrical potential and ground pathways) of the backplane interconnection module to electronic connector 740 of the unit-specific set 510-4. Electronic connector 740 of the unit-specific set 510-4 is connected to electronic connector 730 of computing unit 122-4, enabling electrical power to be supplied to the computing unit from the backplane interconnection module.

Electronic communications can be exchanged between network switches 142-1.1 through 142-1.N of backplane devices 304 and computing units 122-1 and 122-4. For example, on the rear side of backplane interconnection module 212-1, connectors 764-1 through 764-N are connected to connectors 754-1 through 754-N, respectively. As described in further detail with reference to FIG. 11, electronic communications can traverse electrical interconnect pathways of backplane interconnection module 212-1 between connectors 754-1 through 754-N on the rear side of the module and connectors 732-1 through 732-4 for each of computing units 122-1 and 122-4 on the front side of the module. For computing unit 122-1, connectors 742-1 through 742-4 of the unit-specific set 510-1 are connected to connectors 732-1 through 732-4 of the set of unit-side connectors 610-1, respectively. For computing unit 122-4, connectors 742-1 through 742-4 of the unit-specific set 510-4 are connected to connectors 732-1 through 732-4 of the set of unit-side connectors 610-4, respectively.

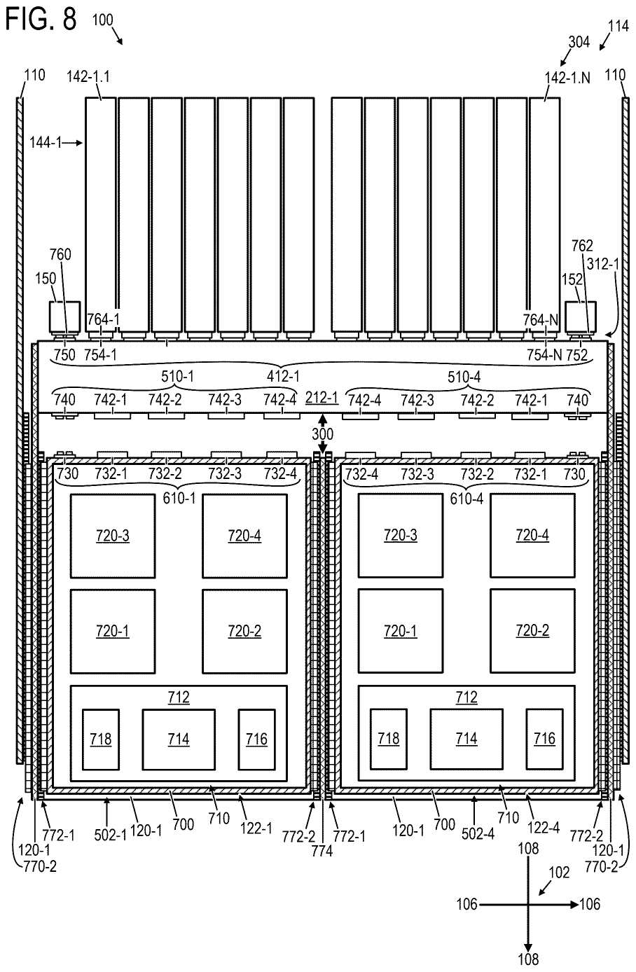

In at least some examples, each of rack trays 112 can be mounted to equipment rack 110 by a pair of rack rails. As described with reference to example rack tray 120-1 of FIG. 7, the rack tray is mounted to equipment rack 110 via a pair of rack rails 770-1 and 770-2. In this example, rack rails 770-1 and 770-2 enable rack tray 120-1 to translate in third dimension 108 (e.g., the depth dimension) between the position depicted in FIG. 7 in which the rack tray is docked with backplane devices 304 to the position depicted in FIG. 8 in which the rack tray is undocked from backplane devices 304. In this example, rack rails 770-1 and 770-2 can assist with alignment of the rear set of connectors 412-1 with the set of backplane-side connectors 312-1 by constraining movement of rack tray 120-1 to translation along third dimension 108, and by limiting or inhibiting movement of rack tray 120-1 in first dimension 104 and second dimension 106. It will be understood that rack rails 770-1 and 770-2 are provided as an example by which each of rack trays 112 can be mounted to equipment rack 110, and that other suitable techniques and associated hardware can be used to mount the rack trays to the equipment rack.

In at least some examples, each computing unit of computing system 100 can be mounted to a corresponding rack tray by a pair of rack rails. As described with reference to example computing units 122-1 and 122-4 of FIG. 7, the computing units are each mounted to rack tray 120-1 via a pair of rack rails 772-1 and 772-2. In this example, rack tray 120-1 includes a dividing wall 774 located between unit bay 502-1 and unit bay 502-4.

In this example, rack rails 770-1 and 770-2 enable rack tray 120-1 to translate in third dimension 108 (e.g., the depth dimension) between the position depicted in FIG. 7 in which the rack tray is docked with backplane devices 304 to the position depicted in FIG. 8 in which the rack tray is undocked from backplane devices 304. In this example, rack rails 770-1 and 770-2 can assist with alignment of the rear set of connectors 412-1 with the set of backplane-side connectors 312-1 by constraining movement of rack tray 120-1 to translation along third dimension 108, and by limiting or inhibiting movement of rack tray 120-1 in first dimension 104 and second dimension 106. It will be understood that rack rails 770-1 and 770-2 are provided as an example by which each of rack trays 112 can be mounted to equipment rack 110, and that other suitable techniques and associated hardware can be used to mount the rack trays to the equipment rack.

Computing units 122-1 and 122-4 of FIG. 7 form a computing tier of computing system 100 in first dimension 104 (e.g., the vertical dimension). In this example, the computing tier of FIG. 7 is connected to backplane devices 304 via a corresponding backplane interconnection module and associated electronic connectors. Other computing tiers of computing system 100 can be similarly configured as the computing tier depicted in FIG. 7, and can be connected to backplane devices via a corresponding backplane interconnection module and associated connectors. For example, computing units of first stacked unit configuration 130 of FIG. 1 can each have the same configuration as computing unit 122-1, and computing units of second stacked unit configuration 132 of FIG. 1 can each have the same configuration as computing unit 122-4. Accordingly, it will be understood that computing unit 122-1 can represent an example computing unit of any other computing unit of stacked unit configuration 130, and that computing unit 122-4 can represent an example computing unit of any other computing unit of stacked unit configuration 132.

FIG. 8 is an elevation view of computing system 100 of FIG. 1 at the same elevation as FIG. 7 in which rack tray 120-1 has been undocked from backplane devices 304 by translating along tray-specific translation path 300 in third dimension 108 while computing units 122-1 and 122-4 are docked with backplane interconnection module 212-1 and remain connected to the backplane interconnection module via their respective connectors.

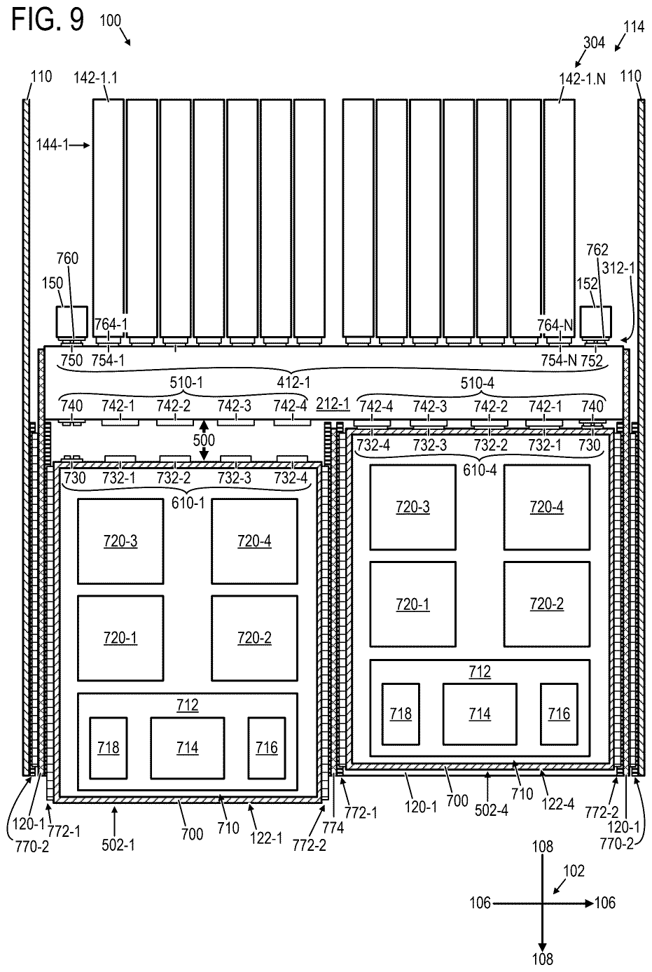

FIG. 9 is an elevation view of computing system 100 of FIG. 1 at the same elevation as FIG. 7 in which computing unit 122-1 has been undocked and is disconnected from backplane interconnection module 212-1 by translating along unit-specific translation path 500 in third dimension 108 while computing unit 122-4 is docked with the backplane interconnection module and remains connected to the backplane interconnection module via its respective connectors. Additionally, in FIG. 9, rack tray 120-1 is docked with backplane devices 304 and remains connected to backplane devices 304. In this example, electrical power can continue to be supplied to computing unit 122-4, and computing unit 122-4 can continue to exchange electronic communications with network switches 142-1.1 through 142-1.N of backplane devices 304.

In the preceding examples described with reference to FIGS. 1-9, electrical power can be supplied by electrical power buses and to the computing units of computing system 100 via the backplane interconnection modules. In other examples, electrical power supplied by the electrical power buses to the computing units of the computing system does not traverse the backplane interconnection modules. In such examples, electronic connectors of the electrical power buses for conveying electrical power can connect to corresponding unit-side electronic connectors of the computing units, as described in further detail with reference to FIG. 10.

FIG. 10 is an elevation view of a computing system 1000 of FIG. 1 at the same elevation as FIG. 7. Computing system 1000 is identical to previously described computing system 100 of FIGS. 1-9 with the exception of the backplane interconnection modules, shape of the rack trays, and relative positioning of the electrical power buses.

In the example of FIG. 10, backplane interconnection module 1212-1 replaces previously described backplane interconnection module 212-1. Connectors 740, 750, and 752 previously described with reference to backplane interconnection module 212-1 are omitted from backplane interconnection module 1212-1 in the example of FIG. 10.

Additionally, in computing system 1000, backplane interconnection module 1212-1 does not extend in the second dimension 106 within a range that would overlap with instances of connector 730 of computing unit 122-1 and 122-4, enabling instances of connector 730 to connect to a corresponding connector of electrical power bus 150 or electrical power bus 152. For example, in computing system 1000, connector 730 of computing unit 122-1 is connected to connector 760 of electrical power bus 150, and connector 730 of computing unit 122-4 is connected to connector 762 of electrical power bus 152.

Additionally, in computing system 1000, a rear portion 1010 of rack tray 120-1 is stepped inward in second dimension 106 to accommodate electrical power buses 150 and 152 in a more proximate location to computing units 122-1 and 122-4 in third dimension 108 as compared to computing system 100.

As previously described, computing units 122-1 and 122-4 of computing system 1000 form a computing tier of the computing system. In the example of FIG. 10, the computing tier is connected to network switches 142-1.1 through 142-1.N of backplane devices 304 via a corresponding backplane interconnection module and associated electronic connectors for conveying electronic communications, whereas electrical power does not traverse the backplane interconnection module. Other computing tiers of computing system 1000 can be similarly configured as the computing tier depicted in FIG. 10, and can be connected to network switches via a corresponding backplane interconnection module and associated connectors, while connections to electrical power buses can bypass the backplane interconnection module.

FIG. 11 is a schematic diagram depicting an example of electrical interconnects of backplane interconnection module 212-1 that can interconnect electronic connectors on rear side 320 with electronic connectors on front side 512 of the module. Backplane interconnection module 212-1 is representative of any of the plurality of backplane interconnection modules of computing system 100.

In FIG. 11, the rear set of module-side electronic connectors 412-1 on rear side 320 of backplane interconnection module 212-1 includes connectors 754-1 through 754-N for conveying electronic communications (e.g., data). As previously described, connectors 754-1 through 754-N can be connected to the set of backplane-side electronic connectors 312-1 of switch tier 144-1 that includes network switches 142-1 through 142-N. Connectors 754-1 through 754-N take the form of multi-lane data connectors in this example.

For each data connector of connectors 754-1 through 754-N on rear side 320, backplane interconnection module 212-1 includes a respective set of electrical interconnects that interconnect that data connector to each other data connector on front side 512 of the backplane interconnection module. This configuration of electrical interconnects enables data to be communicated via any data connector on rear side 320 to any data connector on front side 512 of the backplane interconnection module.

The electrical interconnects of the backplane interconnection modules described herein can take the form of electrical traces on a circuit board and/or electrical cables and/or wires, as examples. Any suitable quantity of electrical interconnects (e.g., traces, cables, wires, etc.) can be used per connector pair to interconnect a first connector on rear side 320 with a second connector on front side 512 of the backplane interconnection module. For example, tens, hundreds, thousands, or more electrical interconnects can be used per connector pair.

As depicted in FIG. 11 with respect to connector 754-1 on rear side 320, a set of electrical interconnects 1110 includes one or more electrical interconnects (e.g., tens, hundreds, thousands, or more) that interconnect connector 754-1 to connector 742-1 of unit-specific set 510-1, one or more electrical interconnects that interconnect connector 754-1 to connector 742-2 of unit-specific set 510-1, one or more electrical interconnects that interconnect connector 754-1 to connector 742-3 of unit-specific set 510-1, and one or more electrical interconnects that interconnect connector 754-1 to connector 742-M of unit-specific set 510-1. The term “M” in this example refers to any suitable quantity of data connectors of the unit-specific set of connectors on front side 512 that are available for connection to an individual computing unit, such as computing unit 122-1 in the preceding examples. For example, the term “M” refers to a fourth connector (742-4) of unit-specific set 510-1 in the example of FIG. 7. Connectors 742-1 through 742-M of unit-specific set 510-1 take the form of multi-lane data connectors, in this example.

Additionally, with respect to connector 754-1, the set of electrical interconnects 1110 further includes one or more electrical interconnects (e.g., tens, hundreds, thousands, or more) that interconnect connector 754-1 to connector 742-1 of unit-specific set 510-4, one or more electrical interconnects that interconnect connector 754-1 to connector 742-2 of unit-specific set 510-4, one or more electrical interconnects that interconnect connector 754-1 to connector 742-3 of unit-specific set 510-4, and one or more electrical interconnects that interconnect connector 754-1 to connector 742-M of unit-specific set 510-4. Again, the term “M” in this example refers to any suitable quantity of data connectors of the unit-specific set of connectors on front side 512 that are available for connection to an individual computing unit, such as computing unit 122-4 in the preceding examples. For example, the term “M” refers to a fourth connector (742-4) of unit-specific set 510-4 in the example of FIG. 7. Connectors 742-1 through 742-M of unit-specific set 510-4 take the form of multi-lane data connectors, in this example.

Electrical interconnects with respect to connectors 754-2 through 754-N are not depicted in FIG. 11 for purposes of illustration and clarity. However, it will be understood that the backplane interconnection module can similarly include a set of electrical interconnects for each of connectors 754-2 through 754-N as previously described with reference to the set of electrical interconnects 1110 to thereby interconnect that data connector to each other data connector on front side 512 of the module.

As further depicted in FIG. 11 with respect to connector 750 on rear side 320, backplane interconnection module 212-1 includes a set of electrical interconnects 1112-1 that interconnect connector 750 to connector 740 of unit-specific set 510-1 on front side 512. In this example, the set of electrical interconnects 1112-1 can convey electrical power supplied at connector 750 to connector 740 of unit-specific set 510-1 (e.g., to power computing unit 122-1). The set of electrical interconnects 1112-1 can include an electrical potential interconnect 1114-1 and an electrical ground interconnect 1116-1, for example.

As further depicted in FIG. 11 with respect to connector 752 on rear side 320, backplane interconnection module 212-1 includes another set of electrical interconnects 1112-2 that interconnect connector 752 to connector 740 of unit-specific set 510-4 on front side 512. In this example, the set of electrical interconnects 1112-2 can convey electrical power supplied at connector 750 to connector 740 of unit-specific set 510-4 (e.g., to power computing unit 122-4). The set of electrical interconnects 1112-2 can include an electrical potential interconnect 1114-2 and an electrical ground interconnect 1116-2, for example.

For each backplane interconnection module, at least some of the rear set of module-side electronic connectors (e.g., 412-1) of each backplane interconnection module can be of a different connector type than at least some of the unit-specific set of module-side electronic connectors (e.g., 510-1, 510-4). For example, with respect to data connectors of the backplane interconnection module, connectors 754-1 through 754-N can each take the form of a first type of multi-lane data connector having a first quantity of lanes, and connectors 740-1 through 740-M can each take the form of a second type of multi-lane data connector having a second quantity of lanes that differs from the first quantity.

Furthermore, in at least some examples, the rear set of module-side electronic connectors (e.g., 412-1) of each backplane interconnection module includes a different connector quantity than each unit-specific set (e.g., 510-1, 510-4) of module-side electronic connectors. For example, the term “M” in 742-M that corresponds to the quantity of unit-side electronic connectors of a computing unit can be greater than or less than the term “N” in 754-N that corresponds to the quantity of network switches of a switch tier.

As previously described with reference to FIG. 10, electrical power connectors can be omitted from the backplane interconnection modules in some examples. In FIG. 10, for example, backplane interconnection module 1212-1 does not include electrical power connectors (e.g., 740, 750, or 752 of FIG. 7). In FIG. 11, portions 1120-1 and 1120-2 of backplane interconnection module 212-1 that are depicted by broken lines can be omitted to provide an example of backplane interconnection module 1212-1 of FIG. 10. For example, portion 1120-1, including the set of electrical interconnects 1112-1 and connectors 740 and 750 contained therein can be omitted from backplane interconnection module 1212-1. Additionally, portion 1120-2, including the set of electrical interconnects 1112-2 and connectors 740 and 752 contained therein can be omitted from backplane interconnection module 1212-1.

According to a first example disclosed herein, a computing system, comprises: an equipment rack; a plurality of backplane devices mounted to the equipment rack to form a backplane connector array that extends in a first dimension and a second dimension that is orthogonal to the first dimension; a plurality of rack trays mounted to the equipment rack in a stacked tray configuration in the first dimension, wherein each rack tray is dockable with two or more of the plurality of backplane devices by independently translating relative to the equipment rack along a tray-specific translation path in a third dimension that is orthogonal to the first dimension and the second dimension; wherein for each rack tray of the plurality of rack trays, the computing system further comprises: one or more backplane interconnection modules mounted to the rack tray in which each backplane interconnection module includes a rear set of two or more module-side electronic connectors on a rear side of the backplane interconnection module that connect to a set of two or more backplane-side electronic connectors of the backplane connector array when the rack tray is docked with the two or more backplane devices, and a plurality of computing units mounted to the rack tray in which each computing unit is dockable with a corresponding backplane interconnection module of the one or more backplane interconnection modules mounted to the rack tray by independently translating relative to the rack tray along a unit-specific translation path in the third dimension; wherein each computing unit includes a set of one or more unit-side electronic connectors that connect to a unit-specific set of one or more module-side electronic connectors on a front side of the corresponding backplane interconnection module when the computing unit is docked with the backplane interconnection module; wherein each backplane interconnection module includes two or more unit-specific sets of module-side electronic connectors for connection to two or more computing units of the plurality of computing units.

In this first example and other examples disclosed herein, the plurality of backplane devices can include a plurality of network switches; and for each of the plurality of rack trays, the two or more backplane devices that are dockable with the rack tray can include two or more network switches of the plurality of network switches arranged in a switch tier that extends in the second dimension.

In this first example and other examples disclosed herein, the plurality of backplane devices can further include one or more electrical power buses; and for each of the plurality of rack trays, the two or more backplane devices that are dockable with the rack tray can further include an electrical power bus of the one or more electrical power buses.

In this first example and other examples disclosed herein, each backplane interconnection module can include a set of electrical interconnects that interconnect the rear set of module-side electronic connectors with each unit-specific set of module-side electronic connectors of the backplane interconnection module.

In this first example and other examples disclosed herein, for each backplane interconnection module, at least some of the rear set of module-side electronic connectors and at least some of each unit-specific set of module-side electronic connectors can take the form of multi-lane data connectors for conveying electronic communications.

In this first example and other examples disclosed herein, for each backplane interconnection module, at least some of the rear set of module-side electronic connectors and at least some of each unit-specific set of module-side electronic connectors can take the form of electrical power connectors for conveying electrical power.

In this first example and other examples disclosed herein, for each backplane interconnection module, at least some of the rear set of module-side electronic connectors can be of a different connector type than at least some of the unit-specific set of module-side electronic connectors.

In this first example and other examples disclosed herein, for each backplane interconnection module, the rear set of module-side electronic connectors can include a different connector quantity than each unit-specific set of module-side electronic connectors.

In this first example and other examples disclosed herein, for each rack tray of the plurality of rack trays, the two or more computing units mounted to the rack tray are concurrently dockable with the corresponding backplane interconnection module.

In this first example and other examples disclosed herein, for each rack tray of the plurality of rack trays, the two or more computing units that are concurrently dockable with the corresponding backplane interconnection module are mounted to the rack tray in a side-by-side unit configuration in the second dimension.

In this first example and other examples disclosed herein, for each rack tray of the plurality of rack trays, each backplane interconnection module mounted to that rack tray extends in the second dimension over a range that spans data connectors of each set of unit-side electronic connectors of the two or more computing units that are connected to the backplane interconnection module.

In this first example and other examples disclosed herein, for each rack tray of the plurality of rack trays, the two or more computing units mounted to the rack tray can include a first stacked unit configuration of two or more computing units in the first dimension, and a second stacked unit configuration of two or more computing units in the first dimension; wherein the first stacked unit configuration and the second stacked unit configuration are side-by-side in the second dimension.

According to a second example disclosed herein, a rack tray mountable to an equipment rack that includes a backplane connector array of a plurality of backplane devices comprises: one or more backplane interconnection modules mounted to the rack tray in which each backplane interconnection module includes: a rear set of two or more module-side electronic connectors on a rear side of the backplane interconnection module for connection to a set of two or more backplane-side electronic connectors of the backplane connector array, and a unit-specific set of two or more module-side electronic connectors on a front side of the backplane interconnection module for connection to a set of one or more unit-side electronic connectors of a corresponding computing unit of the plurality of computing units; wherein each backplane interconnection module includes a set of electrical interconnects that interconnect the rear set of module-side electronic connectors of the backplane interconnection module with the unit-specific set of module-side electronic connectors of the backplane interconnection module.

In this second example and other examples disclosed herein, for each backplane interconnection module, at least some of the rear set of module-side electronic connectors and at least some of the unit-specific set of module-side electronic connectors can take the form of multi-lane electronic connectors for conveying electronic communications.

In this second example and other examples disclosed herein, for each backplane interconnection module, at least some of the rear set of module-side electronic connectors and at least some of the unit-specific set of module-side electronic connectors can take the form of electrical power connectors for conveying electrical power.

In this second example and other examples disclosed herein, for each backplane interconnection module, at least some of the rear set of module-side electronic connectors can be of a different connector type than at least some of the unit-specific set of module-side electronic connectors.

In this second example and other examples disclosed herein, for each backplane interconnection module, the rear set of module-side electronic connectors can include a different connector quantity than the unit-specific set of module-side electronic connectors.

In this second example and other examples disclosed herein, each backplane interconnection module can include two or more unit-specific sets of electronic connectors on the front side of the backplane interconnection module for connection to two or more computing units.

According to a third example disclosed herein, a computing system comprises: an equipment rack; a plurality of backplane devices mounted to the equipment rack to form a backplane connector array that extends in a first dimension and a second dimension that is orthogonal to the first dimension; a plurality of rack trays mounted to the equipment rack in a stacked tray configuration in the first dimension, wherein each rack tray is dockable with two or more of the plurality of backplane devices by independently translating relative to the equipment rack along a tray-specific translation path in a third dimension that is orthogonal to the first dimension and the second dimension; wherein for each rack tray of the plurality of rack trays, the computing system further comprises: one or more backplane interconnection modules mounted to the rack tray in which each backplane interconnection module includes a rear set of two or more module-side electronic connectors on a rear side of the backplane interconnection module that connect to a set of two or more backplane-side electronic connectors of the backplane connector array when the rack tray is docked with the two or more backplane devices, and a plurality of computing units mounted to the rack tray in which each computing unit is dockable with a corresponding backplane interconnection module of the one or more backplane interconnection modules mounted to the rack tray by independently translating relative to the rack tray along a unit-specific translation path in the third dimension; wherein each computing unit includes a set of one or more unit-side electronic connectors that connect to a unit-specific set of one or more module-side electronic connectors on a front side of the corresponding backplane interconnection module when the computing unit is docked with the backplane interconnection module; wherein each backplane interconnection module includes two or more unit-specific sets of module-side electronic connectors for connection to two or more computing units of the plurality of computing units; wherein each backplane interconnection module includes a set of electrical pathways that interconnect the rear set of module-side electronic connectors with each unit-specific set of module-side electronic connectors of the backplane interconnection module.

In this third example and other examples disclosed herein, for each rack tray of the plurality of rack trays, the two or more computing units are concurrently dockable with the same corresponding backplane interconnection module and are mounted to the rack tray in a side-by-side unit configuration in the second dimension.

It will be understood that the configurations and/or approaches described herein are exemplary in nature, and that these specific embodiments or examples are not to be considered in a limiting sense, because numerous variations are possible. The subject matter of the present disclosure includes all novel and non-obvious combinations and sub-combinations of the various processes, systems and configurations, and other features, functions, acts, and/or properties disclosed herein, as well as any and all equivalents thereof.

1. A computing system, comprising:
an equipment rack;
a plurality of backplane devices mounted to the equipment rack to form a backplane connector array that extends in a first dimension and a second dimension that is orthogonal to the first dimension;
a plurality of rack trays mounted to the equipment rack in a stacked tray configuration in the first dimension, wherein each rack tray is dockable with two or more of the plurality of backplane devices by independently translating relative to the equipment rack along a tray-specific translation path in a third dimension that is orthogonal to the first dimension and the second dimension;
wherein for each rack tray of the plurality of rack trays, the computing system further comprises:
one or more backplane interconnection modules mounted to the rack tray in which each backplane interconnection module includes a rear set of two or more module-side electronic connectors on a rear side of the backplane interconnection module that connect to a set of two or more backplane-side electronic connectors of the backplane connector array when the rack tray is docked with the two or more backplane devices, and
a plurality of computing units mounted to the rack tray in which each computing unit is dockable with a corresponding backplane interconnection module of the one or more backplane interconnection modules mounted to the rack tray by independently translating relative to the rack tray along a unit-specific translation path in the third dimension;
wherein each computing unit includes a set of one or more unit-side electronic connectors that connect to a unit-specific set of one or more module-side electronic connectors on a front side of the corresponding backplane interconnection module when the computing unit is docked with the backplane interconnection module;
wherein each backplane interconnection module includes two or more unit-specific sets of module-side electronic connectors for connection to two or more computing units of the plurality of computing units.

2. The computing system of claim 1, wherein the plurality of backplane devices include a plurality of network switches; and
for each of the plurality of rack trays, the two or more backplane devices that are dockable with the rack tray include two or more network switches of the plurality of network switches arranged in a switch tier that extends in the second dimension.

3. The computing system of claim 2, wherein the plurality of backplane devices further include one or more electrical power buses; and
for each of the plurality of rack trays, the two or more backplane devices that are dockable with the rack tray further include an electrical power bus of the one or more electrical power buses.

4. The computing system of claim 1, wherein each backplane interconnection module includes a set of electrical interconnects that interconnect the rear set of module-side electronic connectors with each unit-specific set of module-side electronic connectors of the backplane interconnection module.

5. The computing system of claim 4, wherein for each backplane interconnection module, at least some of the rear set of module-side electronic connectors and at least some of each unit-specific set of module-side electronic connectors take the form of multi-lane data connectors for conveying electronic communications.

6. The computing system of claim 5, wherein for each backplane interconnection module, at least some of the rear set of module-side electronic connectors and at least some of each unit-specific set of module-side electronic connectors take the form of electrical power connectors for conveying electrical power.

7. The computing system of claim 1, wherein for each backplane interconnection module, at least some of the rear set of module-side electronic connectors are of a different connector type than at least some of the unit-specific set of module-side electronic connectors.

8. The computing system of claim 1, wherein for each backplane interconnection module, the rear set of module-side electronic connectors includes a different connector quantity than each unit-specific set of module-side electronic connectors.

9. The computing system of claim 1, wherein for each rack tray of the plurality of rack trays, the two or more computing units mounted to the rack tray are concurrently dockable with the corresponding backplane interconnection module.

10. The computing system of claim 9, wherein for each rack tray of the plurality of rack trays, the two or more computing units that are concurrently dockable with the corresponding backplane interconnection module are mounted to the rack tray in a side-by-side unit configuration in the second dimension.

11. The computing system of claim 1, wherein for each rack tray of the plurality of rack trays, each backplane interconnection module mounted to that rack tray extends in the second dimension over a range that spans data connectors of each set of unit-side electronic connectors of the two or more computing units that are connected to the backplane interconnection module.

12. The computing system of claim 1, wherein for each rack tray of the plurality of rack trays, the two or more computing units mounted to the rack tray include a first stacked unit configuration of two or more computing units in the first dimension, and a second stacked unit configuration of two or more computing units in the first dimension;
wherein the first stacked unit configuration and the second stacked unit configuration are side-by-side in the second dimension.

13. A rack tray mountable to an equipment rack that includes a backplane connector array of a plurality of backplane devices, the rack tray comprising:
one or more backplane interconnection modules mounted to the rack tray in which each backplane interconnection module includes:
a rear set of two or more module-side electronic connectors on a rear side of the backplane interconnection module for connection to a set of two or more backplane-side electronic connectors of the backplane connector array, and
a unit-specific set of two or more module-side electronic connectors on a front side of the backplane interconnection module for connection to a set of one or more unit-side electronic connectors of a corresponding computing unit of the plurality of computing units;
wherein each backplane interconnection module includes a set of electrical interconnects that interconnect the rear set of module-side electronic connectors of the backplane interconnection module with the unit-specific set of module-side electronic connectors of the backplane interconnection module.

14. The rack tray of claim 13, for each backplane interconnection module, at least some of the rear set of module-side electronic connectors and at least some of the unit-specific set of module-side electronic connectors take the form of multi-lane electronic connectors for conveying electronic communications.

15. The rack tray of claim 14, wherein for each backplane interconnection module, at least some of the rear set of module-side electronic connectors and at least some of the unit-specific set of module-side electronic connectors take the form of electrical power connectors for conveying electrical power.

16. The rack tray of claim 13, wherein for each backplane interconnection module, at least some of the rear set of module-side electronic connectors are of a different connector type than at least some of the unit-specific set of module-side electronic connectors.

17. The rack tray of claim 13, wherein for each backplane interconnection module, the rear set of module-side electronic connectors includes a different connector quantity than the unit-specific set of module-side electronic connectors.

18. The rack tray of claim 13, wherein each backplane interconnection module includes two or more unit-specific sets of electronic connectors on the front side of the backplane interconnection module for connection to two or more computing units.

19. A computing system, comprising:
an equipment rack;
a plurality of backplane devices mounted to the equipment rack to form a backplane connector array that extends in a first dimension and a second dimension that is orthogonal to the first dimension;
a plurality of rack trays mounted to the equipment rack in a stacked tray configuration in the first dimension, wherein each rack tray is dockable with two or more of the plurality of backplane devices by independently translating relative to the equipment rack along a tray-specific translation path in a third dimension that is orthogonal to the first dimension and the second dimension;
wherein for each rack tray of the plurality of rack trays, the computing system further comprises:
one or more backplane interconnection modules mounted to the rack tray in which each backplane interconnection module includes a rear set of two or more module-side electronic connectors on a rear side of the backplane interconnection module that connect to a set of two or more backplane-side electronic connectors of the backplane connector array when the rack tray is docked with the two or more backplane devices, and
a plurality of computing units mounted to the rack tray in which each computing unit is dockable with a corresponding backplane interconnection module of the one or more backplane interconnection modules mounted to the rack tray by independently translating relative to the rack tray along a unit-specific translation path in the third dimension;
wherein each computing unit includes a set of one or more unit-side electronic connectors that connect to a unit-specific set of one or more module-side electronic connectors on a front side of the corresponding backplane interconnection module when the computing unit is docked with the backplane interconnection module;
wherein each backplane interconnection module includes two or more unit-specific sets of module-side electronic connectors for connection to two or more computing units of the plurality of computing units.
wherein each backplane interconnection module includes a set of electrical pathways that interconnect the rear set of module-side electronic connectors with each unit-specific set of module-side electronic connectors of the backplane interconnection module.

20. The computing system of claim 19, wherein for each rack tray of the plurality of rack trays, the two or more computing units are concurrently dockable with the same corresponding backplane interconnection module and are mounted to the rack tray in a side-by-side unit configuration in the second dimension.
